(19) United States
(12) Patent Application Publication
(10) Pub. No.: US 2019/0018077 A1
(43) Pub. Date: Jan. 17, 2019

(54) MAGNETO-OPTICAL DEFECT CENTER SENSOR WITH VIBRATION INSENSITIVE PRECISION ADJUSTABILITY

(71) Applicant: LOCKHEED MARTIN CORPORATION, Bethesda, MD (US)

(72) Inventors: Cedric H. WU, Bethesda, MD (US); Joseph W. HAHN, Bethesda, MD (US); Yongdan HU, Bethesda, MD (US)

(73) Assignee: LOCKHEED MARTIN CORPORATION, Bethesda, MD (US)

(21) Appl. No.: 16/032,063

(22) Filed: Jul. 10, 2018

Related U.S. Application Data
(60) Provisional application No. 62/531,328, filed on Jul. 11, 2017.

(51) Int. Cl. G01R 33/032; G01R 33/00; G01R 33/12; G01N 21/64

(52) U.S. Cl. CPC G01R 33/032; G01R 33/0023; G01R 33/1284; G01N 2201/06113; G01N 21/6402; G01N 2021/646; G01N 21/6456

(57) ABSTRACT

Systems for a magneto-optical defect center material magnetic sensor system that uses fluorescence intensity to distinguish the mₛ=±1 states, and to measure the magnetic field based on the energy difference between the mₛ=+1 state and the mₛ=−1 state, as manifested by the RF frequencies corresponding to each state in some embodiments. The system may include an optical excitation source, which directs optical excitation to the material. The system may further include an RF excitation source, which provides RF radiation to the material. Light from the material may be directed through a light pipe to an optical detector. Light from the material may be directed through an optical filter and a lens to be focused at a focal point corresponding to a collection portion of an optical detector.

### CROSS-REFERENCE TO RELATED APPLICATIONS

This application claims the benefit of and priority to U.S. Provisional Application No. 62/531,328 filed on Jul. 11, 2017, the entire disclosure of which is incorporated by reference herein.

### FIELD

The present disclosure generally relates to magneto-optical defect center sensor systems, and more particularly, to magnetic sensor systems including a nitrogen vacancy diamond material.

### BACKGROUND

A number of industrial applications, as well as scientific areas such as physics and chemistry can benefit from magnetic detection and imaging with a device that has extraordinary sensitivity, ability to capture signals that fluctuate very rapidly (bandwidth) all with a substantive package that is extraordinarily small in size and efficient in power. Many advanced magnetic imaging systems can operate in restricted conditions, for example, high vacuum and/or cryogenic temperatures, which can make them inapplicable for imaging applications that require ambient or other conditions. Furthermore, small size, weight and power (SWAP) magnetic sensors of moderate sensitivity, vector accuracy, and bandwidth are valuable in many applications.

### SUMMARY

According to certain implementations, a system for magnetic detection can include a magneto-optical defect center material comprising magneto-optical defect centers, an optical excitation source mounted to a laser optical assembly that may be selectively adjustable in a first axial direction in a first plane relative to the magneto-optical defect center material, and a light collection assembly comprising a light pipe, an optical filter, and a lens. The light collection assembly can be configured to transmit light emitted from the magneto-optical defect center material to the optical detector. The light collection assembly can be selectively adjustable in a second axial direction in the first plane relative to the magneto-optical defect center material.

In some implementations, the laser optical assembly can be selectively adjustable relative to a second plane relative to the magneto-optical defect center material, where the second plane being perpendicular to the first plane. In some implementations, the laser optical assembly can be selectively adjustable relative to a third plane relative to the magneto-optical defect center material, where the third plane being orthogonal to the first plane and the second plane. In some implementations, the laser optical assembly can include a plurality of flexure ribs. In some implementations, the laser optical assembly can include tilt flexure assembly or a tip flexure assembly. In some implementations, the light collection assembly may be selectively adjustable in the second axial direction with a removable light collection assembly adjustment tool. In some implementations, the light pipe may be a hollow tube. In some implementations, the lens may be integrated into the light pipe. In some implementations, the light pipe has a first end proximate the magneto-optical defect center material and a second end proximate the lens.

### BRIEF DESCRIPTION OF THE DRAWINGS

The details of one or more implementations are set forth in the accompanying drawings and the description below. Other features, aspects, and advantages of the disclosure will become apparent from the description, the drawings, and the claims, in which:

FIG. 1 illustrates an orientation of an NV center in a diamond lattice;

FIG. 2 illustrates an energy level diagram showing energy levels of spin states for the NV center;

FIG. 3 illustrates a schematic diagram of a magneto-optical defect center sensor system;

FIG. 4 is a graph illustrating the fluorescence as a function of an applied RF frequency of a magneto-optical defect center along a given direction for a zero magnetic field, and also for a non-zero magnetic field having a component along the defect center axis;

FIG. 5 is a graph illustrating the fluorescence as a function of an applied RF frequency for four different magneto-optical defect center orientations for a non-zero magnetic field;

FIG. 6 is a graphical diagram illustrating a Ramsey pulse sequence;

FIG. 7 is a perspective view illustrating a magneto-optical defect center sensor and showing assemblies for a laser mount and light pipes and lenses for green and red light collection;

FIG. 8 is a top view illustrating the magneto-optical defect center sensor of FIG. 7;

FIG. 9 is a perspective view illustrating the laser mount of FIG. 7;

FIG. 10 is another perspective view illustrating the laser mount of FIG. 7;

FIG. 11 is another perspective view of the laser mount of FIG. 7;

FIG. 12 is a magnified perspective view illustrating a Z-axis adjustment component of the laser mount of FIGS. 9-12;

FIG. 13 is a perspective view illustrating the red light collection assembly of FIG. 7;

FIG. 14 is a cross-section illustrating a hollow light pipe with a collection lens and an associated mount of the red light collection assembly of FIG. 13;

FIG. 15 is a perspective view illustrating the green light collection assembly of FIG. 7;

FIG. 16 is a cross-section illustrating a light pipe with a collection lens and an associated mount of the green light collection assembly of FIG. 15;

FIG. 17 is a perspective view illustrating a light collection assembly adjustment tool for adjusting the light collection assemblies;

FIG. 18 is a perspective view illustrating the light collection assembly adjustment tool of FIG. 17 engaged with the red light collection assembly of FIG. 13; and

FIG. 19 illustrates a process for assembling and adjusting the laser mount assembly and light collection assemblies.

It will be recognized that some or all of the figures are schematic representations for purposes of illustration. The figures are provided for the purpose of illustrating one or more embodiments with the explicit understanding that they will not be used to limit the scope or the meaning of the claims.

### DETAILED DESCRIPTION

Following below are more detailed descriptions of various concepts related to, and implementations of, methods, apparatuses, and systems for a vibration insensitive precision adjustability system for a magneto-optical defect center sensor.

Atomic-sized magneto-optical defect centers, such as nitrogen-vacancy (NV) centers in diamond lattices, have excellent sensitivity for magnetic field measurement and enable fabrication of small magnetic sensors. Magneto-optical defect center materials include but are not be limited to diamonds, Silicon Carbide (SiC), Phosphorous, and other materials with nitrogen, boron, carbon, silicon, or other defect centers. Magneto-optical defect center sensors, such as a diamond nitrogen vacancy (DNV) sensor, can be maintained in room temperature and atmospheric pressure and can be even used in liquid environments. For a DNV sensor, a green optical source (e.g., a micro-LED) can optically excite NV centers of the DNV sensor and cause emission of fluorescence radiation (e.g., red light) under off-resonant optical excitation. A magnetic field generated, for example, by a microwave coil can probe triplet spin states (e.g., with mₛ=−1, 0, +1) of the NV centers to split in relation to an external magnetic field projected along the NV axis, resulting in two spin resonance frequencies. The difference between the two spin resonance frequencies can correlate to a measure of the strength of the external magnetic field. A photo detector can measure the fluorescence (red light) emitted by the optically excited NV centers.

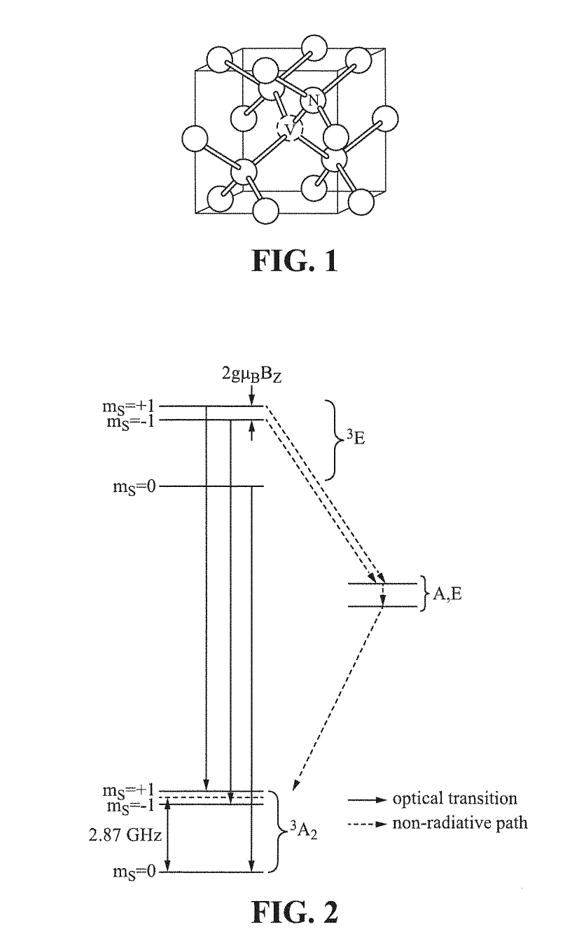

Nitrogen-vacancy centers (NV centers) are defects in a diamond's crystal structure, which can purposefully be manufactured in synthetic diamonds as shown in FIG. 1. In general, when excited by green light and microwave radiation, the NV centers cause the diamond to generate red light. When excited with green light, the NV defect centers generate red light fluorescence. After sufficient time (on order of nanoseconds to microseconds) the fluorescence counts stabilize. When microwave radiation is added, the NV electron spin states are changed, and this results in a change in intensity of the red fluorescence. The changes in fluorescence may be recorded as a measure of electron spin resonance. By measuring the changes, the NV centers may be used to accurately detect the magnetic field strength.

The NV center may exist in a neutral charge state or a negative charge state. Conventionally, the neutral charge state uses the nomenclature NV⁰, while the negative charge state uses the nomenclature NV, which is adopted in this description.

The NV center may have a number of electrons, including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

The NV center has rotational symmetry and, as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of approximately 2.87 GHz for a zero external magnetic field.

Introducing the external magnetic field with the component along the NV axis lifts the degeneracy of the mₛ=±1 energy levels, splitting the energy levels mₛ=±1 by an amount 2gμ_{B}B_{z}, where g is the Lande g-factor, μ_{B} is the Bohr magneton, and B_{z} is the component of the external magnetic field along the NV axis. This relationship is correct to a first order and inclusion of higher order corrections is a straightforward matter.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states that have the same spin. For a direct transition between the excited triplet ³E and the ground state ³A₂, a photon of red light is emitted with a photon energy corresponding to the energy difference between the energy levels of the transitions.

There is, however, an alternative non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than the transition rate from the mₛ=0 spin state of the excited triplet ³E to the intermediate energy levels. The transition from the singlet states A, E to the ground state triplet ³A₂ predominantly decays to the mₛ=0 spin state over the mₛ=±1 spins states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A_{z} may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

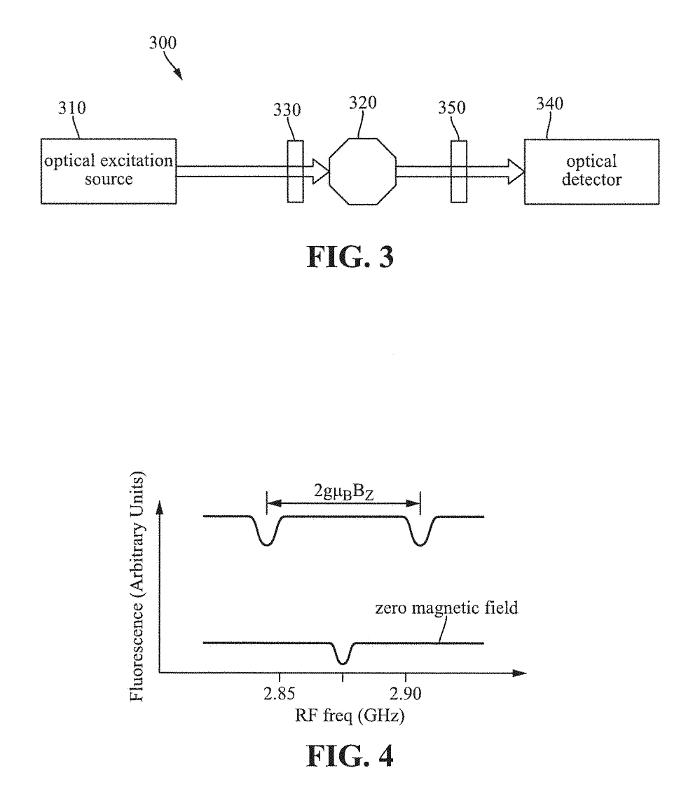

FIG. 3 is a schematic diagram illustrating a magneto-optical defect center sensor system 300 that uses fluorescence intensity to distinguish the mₛ=±1 states, and to measure the magnetic field based on the energy difference between the mₛ=+1 state and the mₛ=−1 state, as manifested by the RF frequencies corresponding to each state. The system 300 includes an optical excitation source 310, which directs optical excitation to a magneto-optical defect center material 320 with magneto-optical defect centers. The system further includes an RF excitation source 330, which provides RF radiation to the magneto-optical defect center material 320. Light from the magneto-optical defect center material may be directed through an optical filter 350 to an optical detector 340.

The RF excitation source 330 may be a microwave coil, for example. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance and a subsequent decrease in fluorescence intensity occurs between the mₛ=0 spin state and the mₛ=−1 spin state of the ground state when the photon energy of the RF radiation emitted by the RF excitation source 330 is the difference in energies of the mₛ=0 spin state and the mₛ=−1 spin state.

The optical excitation source 310 may be a laser or a light emitting diode, for example, which emits light in the green (light having a wavelength such that the color is green), for example. The optical excitation source 310 induces fluorescence in the red, which corresponds to an electronic transition from the excited state to the ground state. Light from the magneto-optical defect center material 320 may be directed through the optical filter 350 to filter out light in the excitation band (in the green, for example), and to pass light in the red fluorescence band, which in turn may be detected by the detector 340. The optical excitation light source 310, in addition to exciting fluorescence in the magneto-optical defect center material 320, also serves to reset the population of the mₛ=0 spin state of the ground state ³A₂ to a maximum polarization, or other desired polarization.

For continuous wave excitation, the optical excitation source 310 continuously pumps the magneto-optical defect centers, and the RF excitation source 330 sweeps across a frequency range, which includes the zero splitting (when the mₛ=±1 spin states have the same energy) photon energy of approximately 2.87 GHz for NV centers. The fluorescence for an RF sweep corresponding to a magneto-optical defect center material 320 with magneto-optical defect centers aligned along a single direction is shown in FIG. 4 for different magnetic field components B_{z} along the magneto-optical defect axis, where the energy splitting between the mₛ=−1 spin state and the mₛ=+1 spin state increases with B_{z}. Thus, the component B_{z} may be determined. Optical excitation schemes other than continuous wave excitation are contemplated, such as excitation schemes involving pulsed optical excitation, and pulsed RF excitation. Examples of pulsed excitation schemes include Ramsey pulse sequence (described in more detail below), spin echo pulse sequence, etc.

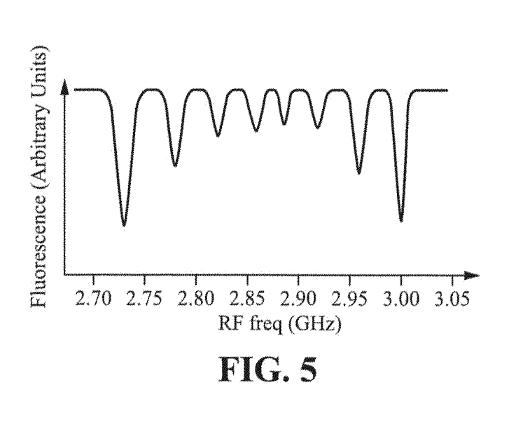

In general, the magneto-optical defect center material 320 will have magneto-optical defect centers aligned along directions of four different orientation classes. FIG. 5 illustrates fluorescence as a function of RF frequency for the case where the magneto-optical defect center material 320 has magneto-optical defect centers aligned along directions of four different orientation classes. In this case, the component B_{z} along each of the different orientations may be determined. These results, along with the known orientation of crystallographic planes of a magneto-optical defect material lattice, allow not only the magnitude of the external magnetic field to be determined, but also the direction of the magnetic field.

While FIG. 3 illustrates a magneto-optical defect center sensor system 300 with a magneto-optical defect center material 320 having a plurality of magneto-optical defect centers, such as a DNV material with NV centers. In general, the magnetic sensor system may instead employ a different magneto-optical defect center material with a plurality of magneto-optical defect centers. Magneto-optical defect center materials include but are not be limited to diamonds, Silicon Carbide (SiC), Phosphorous, and other materials with nitrogen, boron, carbon, silicon, or other defect centers. The electronic spin state energies of the magneto-optical defect centers shift with magnetic field, and the optical response, such as fluorescence, for the different spin states may be not the same for all of the different spin states. In this way, the magnetic field may be determined based on optical excitation, and possibly RF excitation, in a corresponding way to that described above with magneto-optical defect center material.

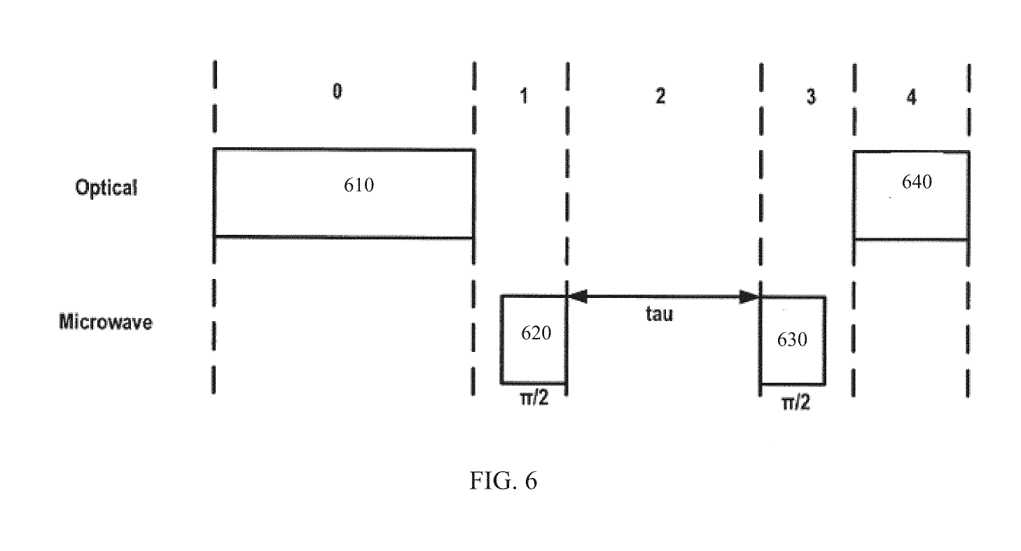

A Ramsey pulse sequence is a pulsed RF laser scheme that is believed to measure the free precession of the magnetic moment in the magneto-optical defect center material 320 with magneto-optical defect centers, and is a technique that quantum mechanically prepares and samples the electron spin state. FIG. 6 is an example of a schematic diagram illustrating the Ramsey pulse sequence. As shown in FIG. 6, a Ramsey pulse sequence includes optical excitation pulses and RF excitation pulses over a five-step period. In a first step, during a period 0, a first optical excitation pulse 610 is applied to the system to optically pump electrons into the ground state (i.e., mₛ=0 spin state). This is followed by a first RF excitation pulse 620 (in the form of, for example, a microwave (MW) π/2 pulse) during a period 1. The first RF excitation pulse 620 sets the system into superposition of the mₛ=0 and mₛ=+1 spin states (or, alternatively, the mₛ=0 and mₛ=−1 spin states, depending on the choice of resonance location). During a period 2, the system is allowed to freely precess (and dephase) over a time period referred to as tau (τ). During this free precession time period, the system measures the local magnetic field and serves as a coherent integration. Next, a second RF excitation pulse 630 (in the form of, for example, a MW π/2 pulse) is applied during a period 3 to project the system back to the mₛ=0 and mₛ=+1 basis. Finally, during a period 4, a second optical pulse 640 is applied to optically sample the system and a measurement basis is obtained by detecting the fluorescence intensity of the system. The RF excitation pulses applied are provided at a given RF frequency in relation to the Lorentzians such as referenced in connection with FIG. 5.

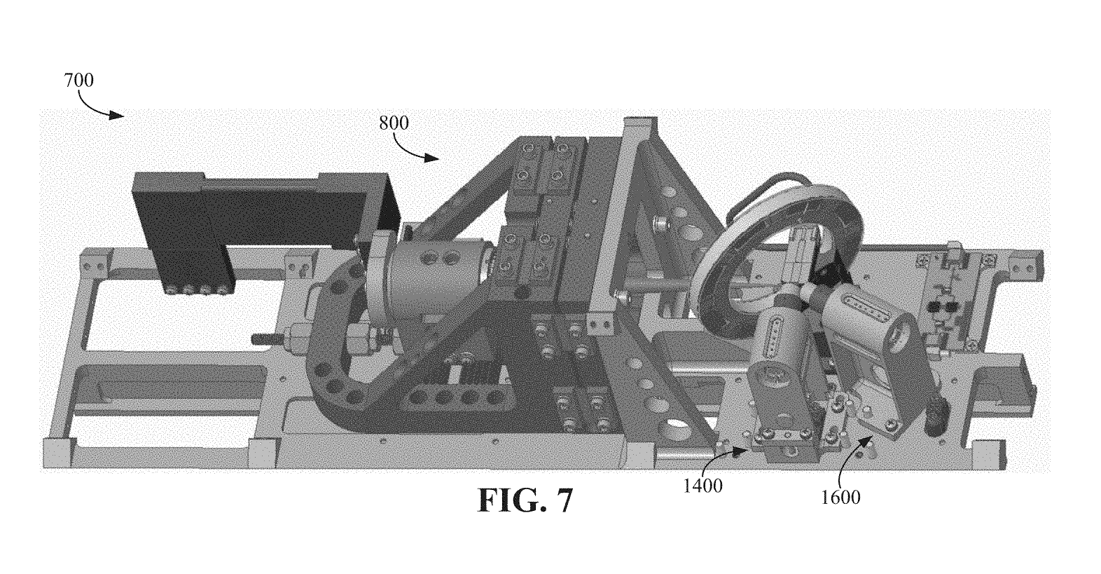

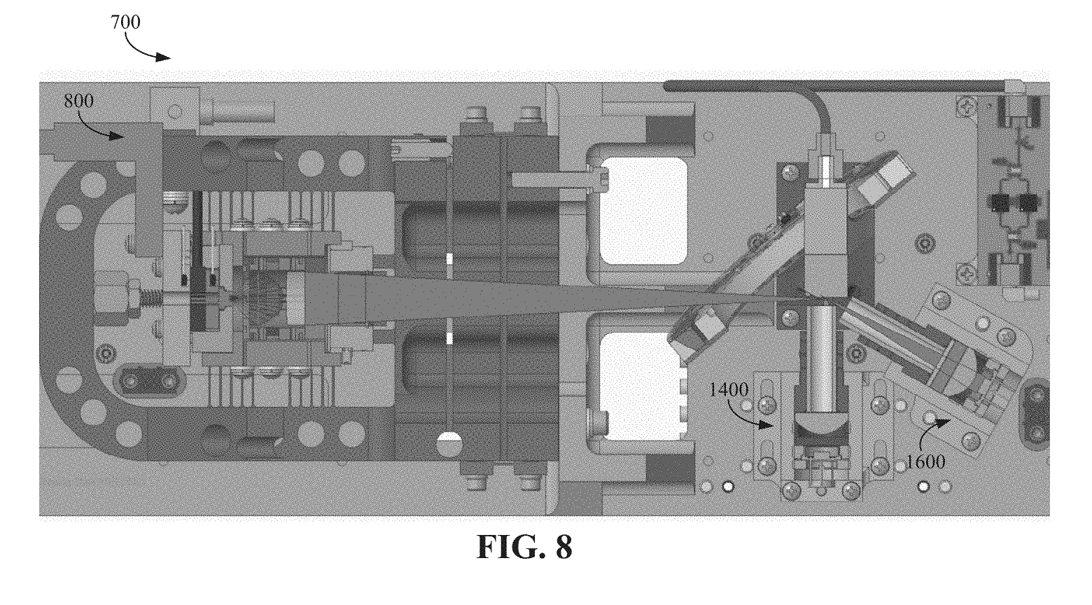

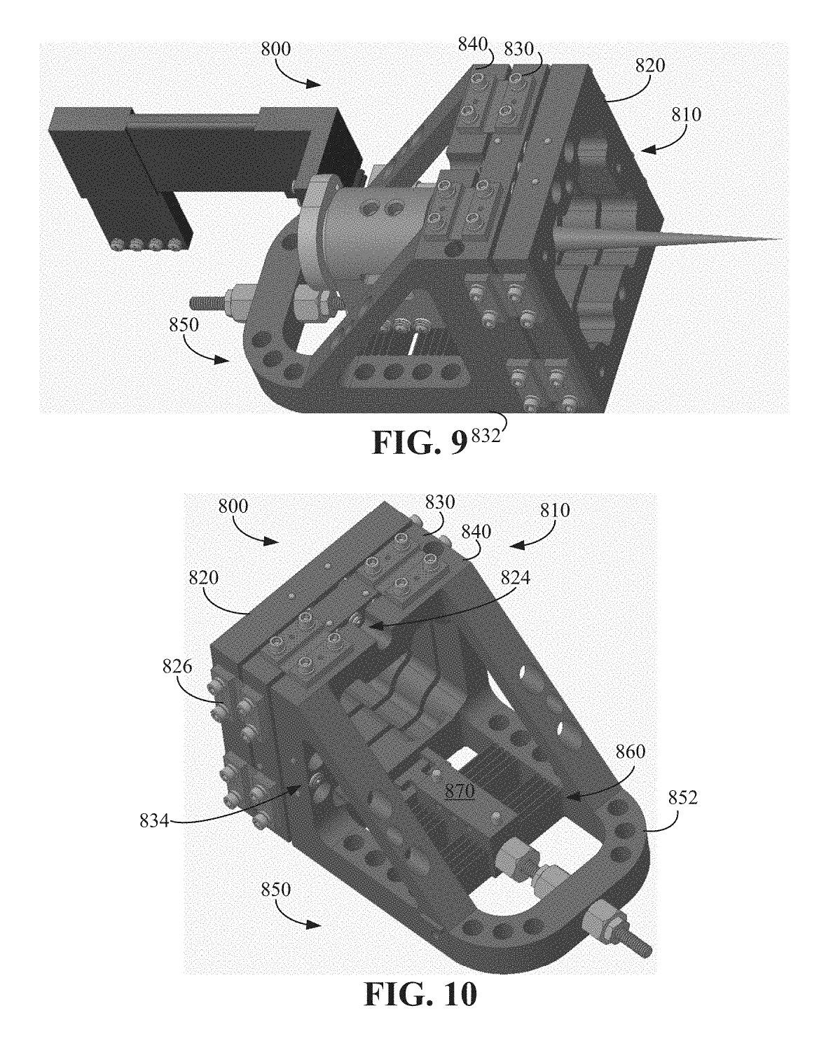

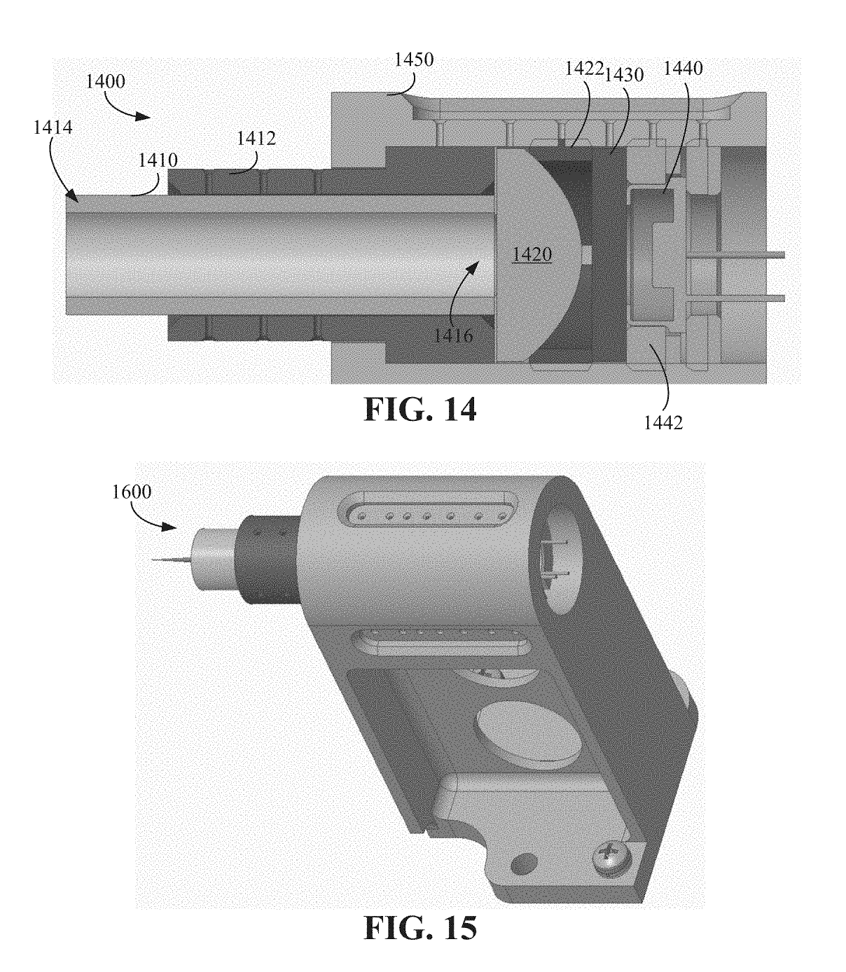

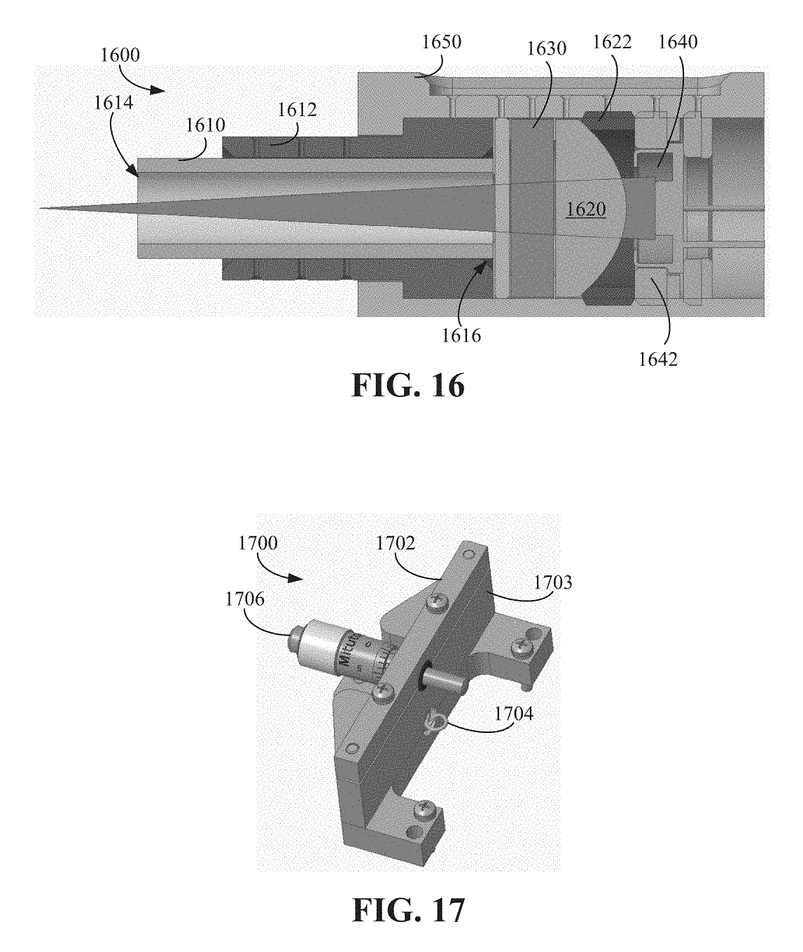

FIG. 7 is perspective view depicting a magneto-optical defect center sensor 700 and showing a laser mount assembly 800 and assemblies 1400, 1600 for light pipes and lenses for green and red light collection. As shown generally in FIGS. 7-8, green light may be emitted from a laser optical assembly and focused on a magneto-optical defect center material, such as a diamond having nitrogen vacancies. The laser mount assembly 800 for the laser optical assembly is described in greater detail below in reference to FIGS. 9-12. The red light collection assembly 1400 may be positioned relative to the magneto-optical defect center material to collect the red light emitted. The red light collection assembly 1400 is described in greater detail below in reference to FIGS. 13-14. The green light collection assembly 1600 may be positioned relative to the magneto-optical defect center material to collect the green light that passes through the magneto-optical defect center material that does not fluoresce into red light from the magneto-optical defect centers. In the implementation shown, the green light collection assembly 1600 may be offset at an angle of approximately 29.25 degrees based on the geometric configuration of the magneto-optical defect center material. The green light collection assembly 1600 is described in greater detail below in reference to FIGS. 15-16.

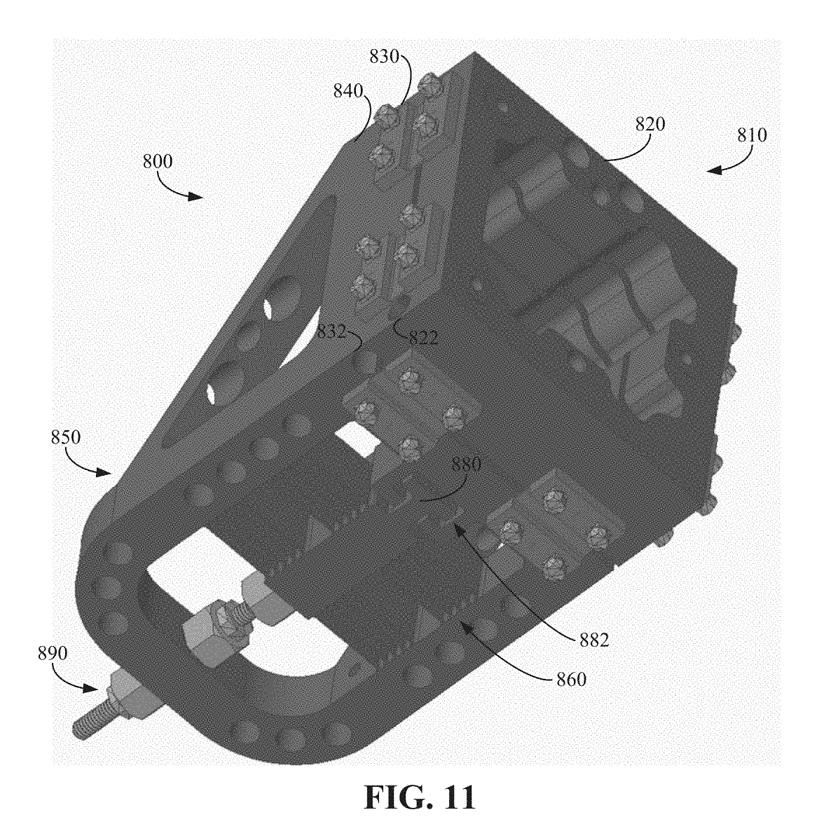

FIGS. 9-12 generally depict the laser optical assembly 800. The laser optical assembly 800 includes a tip and tilt flexure assembly 810 and a Z-axis adjustment assembly 850. The tip and tilt flexure assembly 810 includes a first frame member portion 820, a second frame member portion 830, and a third frame member portion 840. The first frame member portion 820 may be substantially separated from the second frame member portion 830 except for a tilt flexure rib 822 coupling the first frame member portion 820 to the second frame member portion 830, as shown in FIG. 11. The tilt flexure rib 822 can be approximately 0.050 inches to permit flexure of the first frame member portion 820 relative to the second frame member portion 830, without plastically deforming the tilt flexure rib 822. A nudger 824 may be used to finely adjust the tilt angle of the first frame member portion 820 relative to the second frame member portion 830. In some implementations, the nudger 824 can include one or more springs, such as two springs, to assist retracting or pushing the first frame member portion 820 relative to the second frame member portion 830. In some implementations, one or more fixation straps 826 can be affixed, either mechanically via screws, adhesively, or both, to the first frame member portion 820 and the second frame member portion 830 to secure the first frame member portion 820 relative to the second frame member portion 830. In some implementations, the nudger 824 and/or screws of the fixation straps 826 can be removed to reduce the weight of the assembly once secured in position. In other implementations, the nudger 824 and/or screws of the fixation straps 826 can remain in place during operation.

The second frame member portion 830 may be substantially separated from the third frame member portion 840 except for a tip flexure rib 832 coupling the second frame member portion 830 to the third frame member portion 840, as shown in FIG. 11. The tip flexure rib 832 can be approximately 0.050 inches to permit flexure of the second frame member portion 830 relative to the third frame member portion 840, without plastically deforming the tip flexure rib 832. A nudger 834 may be used to finely adjust the tilt angle of the second frame member portion 830 relative to the third frame member portion 840. In some implementations, the nudger 834 can include one or more springs, such as two springs, to assist retracting or pushing the second frame member portion 830 relative to the third frame member portion 840. In some implementations, one or more fixation straps 826 can be affixed, either mechanically via screws, adhesively, or both, to the second frame member portion 830 and the third frame member portion 840 to secure the second frame member portion 830 relative to the third frame member portion 840. In some implementations, the nudger 834 and/or screws of the fixation straps 826 can be removed to reduce the weight of the assembly once secured in position. In other implementations, the nudger 834 and/or screws of the fixation straps 826 can remain in place during operation.

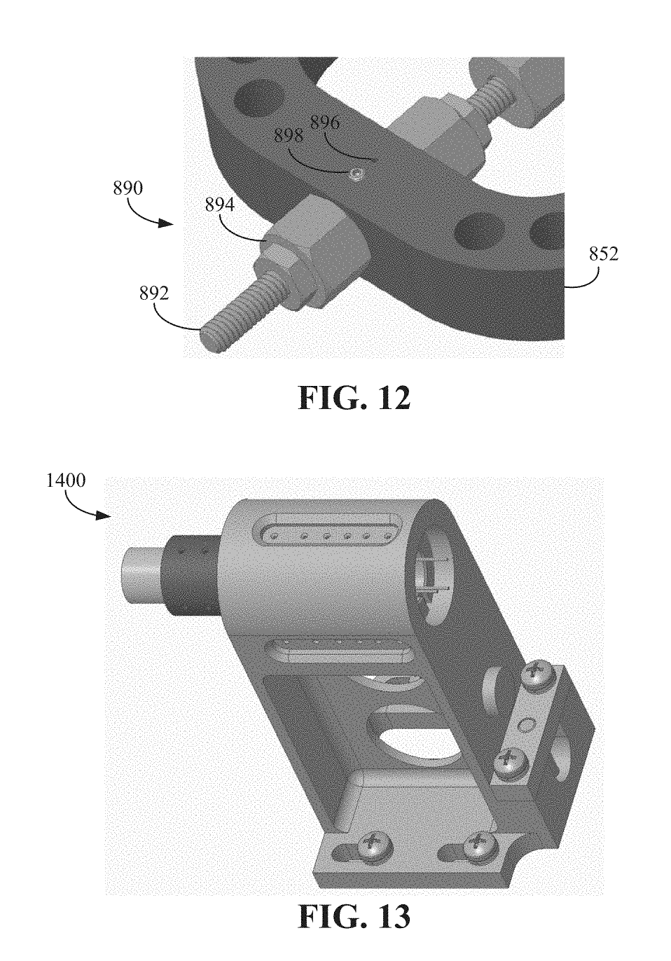

As shown in FIGS. 9-11, the Z-axis adjustment assembly 850 includes an outer frame member 852 and a plurality of flexure ribs 860 connecting the outer frame member 852 to a laser mount 870. In the implementation shown, the plurality of flexure ribs 860 include four sets of five flexure ribs 860, with two sets of five ribs on each side. The flexure ribs 860 can be approximately 0.050 inches to permit flexure of the flexure ribs 860 to adjust a Z-axis position of the laser mount 870 relative to the outer frame member 852. As shown in FIG. 11, a motion limiter 880, such as a T-shaped member, can be positioned within a channel 882 to limit the maximum movement of the laser mount 870 relative to the outer frame member 852 to limit the maximum deformation of the plurality of flexure ribs 860. The Z-axis adjustment assembly 850 includes a Z-axis adjustment component 890, shown in FIG. 12. The Z-axis adjustment component 890 includes a threaded rod 892 coupled to nuts 894 secured relative to the laser mount 870 and the outer frame member 852. The threaded rod 892 and/or the nuts 894 are rotated to selectively adjust the position of the laser mount 870 relative to the outer frame member 852 while the plurality of flexure ribs 860 flex. The outer frame member 852 includes an opening 896 through which an adhesive can be applied to secure the threaded rod 892 relative to the outer frame member 852. In some implementations, a set screw 898 can be used to secure the threaded rod 892 relative to the outer frame member 852, either in lieu of the adhesive or in addition thereto.

FIGS. 13-14 depict an implementation of a red light collection assembly 1400. The red light collection assembly 1400 includes an optical light pipe 1410, a light pipe mount 1412, a lens 1420, a lens retention ring 1422, a red filter 1430, a photo diode 1440, a photo diode mount 1442, and the assembly mount 1450. The assembly mount 1450 includes slotted openings 1452 to selectively adjust a Z-axis of the red light collection assembly 1400 relative to the magneto-optical defect center material.

The optical light pipe 1410 may be a hollow copper tube having a highly reflective interior surface to reflect the light within the light pipe 1410. The air within the hollow tube may be substantially lossless for optical transmission. In some implementations, the reflective interior surface can be a silver layer. In other implementations, the reflective interior surface can be configured to minimize optical losses at a specific wavelength, such as 650 nanometers (nm) to 850 nm. In other implementations, the inner surface of the light pipe 1410 can incorporate an optical filtering coating to absorb or filter wavelengths of light that are not of interest. In some instances, the light pipe 1410 may have a 5 millimeter (mm) inner diameter, a 7 mm outer diameter, and be 25 mm in length. The light pipe 1410 may be coupled or staked to the light pipe mount 1412 via adhesive within one or more openings formed in the light pipe mount 1412. The light pipe mount 1412 may be secured within the assembly mount 1450 via adhesive within one or more openings formed in the assembly mount 1450. The light pipe 1410 may be positioned proximate the magneto-optical defect center material at a first end 1414 and may be positioned proximate a lens 1420 at a second end 1416. In some implementation, a spacer washer can be positioned between the second end 1416 and the lens 1420.

The lens 1420 may be an aspheric lens positioned to focus the light exiting the light pipe 1410 from the second end 1416 to a focal point corresponding to a collection portion of the photo diode 1440. Thus, by positioning the lens 1420 directly downstream of the light pipe 1410, substantially all of the light exiting the light pipe 1410 may be collected by the photo diode 1440. A lens retention ring 1422 mechanically secures the lens 1420 in position within the assembly mount 1450. In addition, the lens 1420 and lens retention ring 1422 can also be secured within the assembly mount 1450 via adhesive within one or more openings formed in the assembly mount 1450. In some implementations, the lens 1420 may be positioned within the light pipe 1410 and/or may be integrally formed with the light pipe 1410.

A red filter 1430 may be positioned proximate the lens 1420 to filter out wavelengths of light that do not correspond to a wavelength of interest, such as 650 nm to 850 nm. In some implementations, the red filter 1430 may be a coating on the lens 1420 and/or may be incorporated integrally into the lens 1420 itself. The red filter 1430 can also be secured within the assembly mount 1450 via adhesive within one or more openings formed in the assembly mount 1450.

A photo diode 1440 may be positioned such that the collection portion may be located at the focal point of the lens 1420. The photo diode 1440 can be coupled to a photo diode mount 1442 to center the photo diode 1440 within the assembly mount 1450. In some implementations, the photo diode mount 1442 can also be secured within the assembly mount 1450 via adhesive within one or more openings formed in the assembly mount 1450. In some implementations, a retaining ring can be used to axially secure the photo diode mount 1442 within the assembly mount 1450.

In some implementations, the optical light pipe 1410 may be a solid glass pipe having a highly reflective coating to reflect the light within the light pipe 1410. In some implementations, the reflective coating can be configured to minimize optical losses at a specific wavelength, such as 650 nm to 1450 nm. In other implementations, the light pipe 1410 itself can incorporate an optical filtering material to absorb or filter wavelengths of light that are not of interest. In some instances, the light pipe 1410 may be a hexagonal solid borosilicate glass material. The light pipe 1410 may be coupled to the light pipe mount 1412 via a compressible portion of the light pipe mount 1412 that may be clamped down to secure the light pipe 1410 to the light pipe mount 1412.

FIGS. 15-16 depicts an implementation of a green light collection assembly 1600. The green light collection assembly 1600 includes an optical light pipe 1610, a light pipe mount 1612, a green filter 1630, a lens 1620, a lens retention ring 1622, a photo diode 1640, a photo diode mount 1642, and the assembly mount 1650. In some implementations, the assembly mount 1650 can include slotted openings to selectively adjust the axial position of the green light collection assembly 1600 relative to the magneto-optical defect center material.

The optical light pipe 1610 may be a hollow copper tube having a highly reflective interior surface to reflect the light within the light pipe 1610. The air within the hollow tube may be substantially lossless for optical transmission. In some implementations, the reflective interior surface can be a silver layer. In other implementations, the reflective interior surface can be configured to minimize optical losses at a specific wavelength, such as 500 nm to 550 nm. In other implementations, the inner surface of the light pipe 1610 can incorporate an optical filtering coating to absorb or filter wavelengths of light that are not of interest. In some instances, the light pipe 1610 may have a 5 millimeter (mm) inner diameter, a 7 mm outer diameter, and be 25 mm in length. The light pipe 1610 may be coupled or staked to the light pipe mount 1612 via adhesive within one or more openings formed in the light pipe mount 1612. The light pipe mount 1612 may be secured within the assembly mount 1650 via adhesive within one or more openings formed in the assembly mount 1650. The light pipe 1610 may be positioned proximate the magneto-optical defect center material at a first end 1614 and may be positioned proximate a green filter 1630 at a second end 1616. In some implementation, a spacer washer can be positioned between the second end 1616 and the green filter 1630.

A green filter 1630 may be positioned proximate the lens 1620 to filter out wavelengths of light that do not correspond to a wavelength of interest, such as 500 nm to 550 nm. In some implementations, multiple green filters 1630 may be used depending on the intensity of light. In some implementations, the green filter 1630 may be a coating on the lens 1620 and/or may be incorporated integrally into the lens 1620 itself. The green filter 1630 can also be secured within the assembly mount 1650 via adhesive within one or more openings formed in the assembly mount 1650.

The lens 1620 may be an aspheric lens positioned to focus the light exiting the light pipe 1610 to a focal point corresponding to a collection portion of the photo diode 1640. Thus, by positioning the lens 1620 downstream of the light pipe 1610, substantially all of the light exiting the light pipe 1610 may be collected by the photo diode 1640. A lens retention ring 1622 mechanically secures the lens 1620 in position within the assembly mount 1650. In addition, the lens 1620 and lens retention ring 1622 can also be secured within the assembly mount 1650 via adhesive within one or more openings formed in the assembly mount 1650. In some implementations, the lens 1620 may be positioned within the light pipe 1610 and/or may be integrally formed with the light pipe 1610.

A photo diode 1640 may be positioned such that the collection portion may be located at the focal point of the lens 1620. The photo diode 1640 can be coupled to a photo diode mount 1642 to center the photo diode 1640 within the assembly mount 1650. In some implementations, the photo diode mount 1642 can also be secured within the assembly mount 1650 via adhesive within one or more openings formed in the assembly mount 1650. In some implementations, a retaining ring can be used to axially secure the photo diode mount 1642 within the assembly mount 1650.

In some implementations, the filters and lenses described herein can be incorporated into a customized photo diode to integrate the components into a compact package.

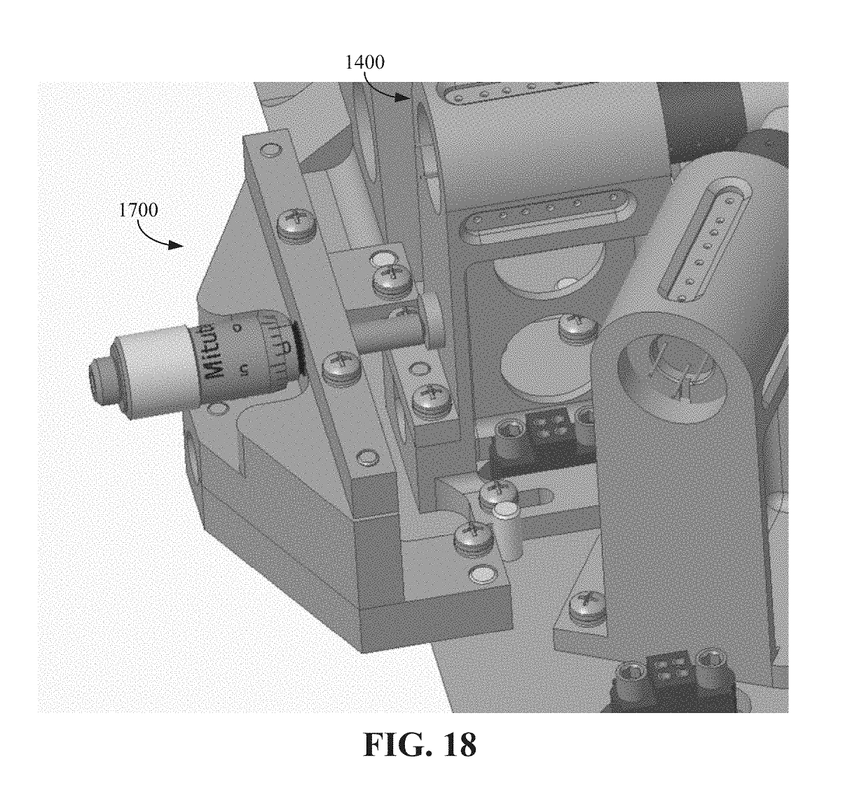

FIG. 17 depicts a light collection assembly adjustment tool 1700. The light collection assembly adjustment tool 1700 includes a frame 1702, a spring 1704 coupled to the frame 1702, and a micrometer 1706 coupled to the frame 1702 and configured to selectively extend and retract a rod relative to a surface 1703 of the frame 1702. As shown in FIG. 18, the light collection assembly adjustment tool 1700 includes alignment pins that can be inserted into openings in a base mount of the magneto-optical defect center sensor and the spring 1704 can be attached to a pin (not shown) of a light collection assembly, such as the red light collection assembly 1400. The rod of the micrometer 1706 can be selectively extended or retracted relative to the surface 1703 of the frame 1702 to adjust the Z-axis position of the light collection assembly relative to the light collection assembly adjustment tool 1700. The spring 1704 retains the light collection assembly against the rod of the micrometer 1706 by providing a counter spring force. Once the light collection assembly is positioned, the light collection assembly adjustment tool 1700 can be remove to reduce the weight adjustment components to reduce vibration from the magneto-optical defect center sensor.

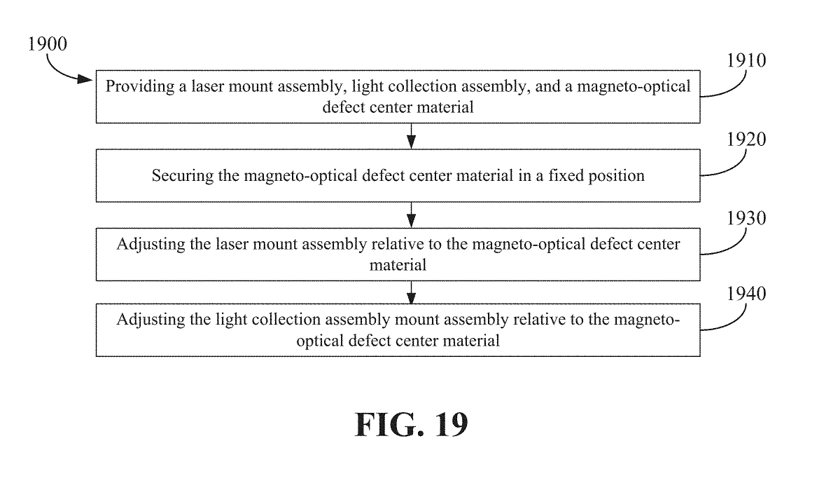

FIG. 19 depicts a process 1900 for process for assembling and adjusting the laser mount assembly 800 and light collection assemblies 1400, 1600. The process 1900 includes providing a laser mount assembly 800, light collection assembly 1400, 1600, and a magneto-optical defect center material (block 1910). The process 1900 includes securing the magneto-optical defect center material in a fixed position (block 1920). Securing of the magneto-optical defect center material can include mounting the magneto-optical defect center material to a mount and securing the mount on a base plate.

The process 1900 includes mounting the laser mount assembly 800 and adjusting the laser mount assembly 800 relative to the magneto-optical defect center material (block 1930). Adjusting the laser mount assembly 800 relative to the magneto-optical defect center material can include adjusting the tip, tilt, and/or Z-axis position. The tip and tilt can be adjusted using the tilt flexure rib 822 and tip flexure rib 832 with the nudgers 824, 834 to adjust lensing of a laser assembly to optically focus an optical excitation source at a point and/or plane of the magneto-optical defect center material. The Z-axis position can adjust the Z-axis focal point of the optical excitation by moving the laser mount 870 in the Z-axis using the Z-axis adjustment assembly 850. In some implementations, the fixation straps 826 can be fixed for the tip/tilt prior to adjusting the Z-axis. The Z-axis position can then be adjusted and fixed in position. In other implementations, an iterative process can be implemented to fine tune the tip, tilt, and Z-axis position of the focal point and/or plane of the optical excitation source relative to the magneto-optical defect center material.

The process 1900 includes mounting a light collection assembly 1400, 1600 and adjusting the light collection assembly 1400, 1600 relative to the magneto-optical defect center material (block 1940). Adjusting the light collection assembly 1400, 1600 relative to the magneto-optical defect center material can include adjusting the Z-axis position to position the light collection assembly 1400, 1600 for maximum light collection at the photo diode. The Z-axis position can be adjusted using the light collection assembly adjustment tool 1700. In some implementations, the light collection assembly 1400, 1600 can be fixed by mechanically and/or adhesively.

In some implementations, an iterative process can be implemented to fine tune the tip, tilt, and Z-axis position of the focal point and/or plane of the optical excitation source relative to the magneto-optical defect center material and the Z-axis position of the light collection assembly 1400, 1600.

The laser mount assembly 800 and the light collection assemblies 1400, 1600 utilize minimal mounting hardware and separate the fine tuning adjustability components from the magneto-optical defect center sensor such that fewer components are used, thereby reducing the components that can vibrate and also minimizes the weight of the magneto-optical defect center sensor. The flexure provided by the Z-axis adjustment assembly, the tilt flexure assembly, and the tip flexure assembly utilize the resiliency of the material of the laser mount assembly to provide adjustability without additional hardware that can introduce additional tolerances that can result in additional vibration when subjected to stress. In addition, the separation of the light collection assembly adjustment tool 1700 from the light collection assemblies 1400, 1600 permits fine-tuned adjustment for aligning the light collection assemblies 1400, 1600, but removes the adjustment component when the magneto-optical defect sensor is to be deployed, thereby reducing the weight and any vibration that may be introduce by such fine-tuning components. Further, the usage of adhesives for the light collection assemblies 1400, 1600 and/or the laser mount assembly minimizes mechanical components and the corresponding tolerances that can result in additional vibration when introduced to shock loads. Such vibration insensitivity improves the magneto-optical defect sensor over laboratory equipment where vibrations and other environmental conditions are minimal.

The description is provided to enable any person skilled in the art to practice the various embodiments described herein. While some embodiments have been particularly described with reference to the various figures and configurations, it should be understood that these are for illustration purposes only and should not be taken as limiting the scope of the subject technology.

There may be many other ways to implement. Various functions and elements described herein may be partitioned differently from those shown without departing from the scope of the subject technology. Various modifications to these embodiments may be readily apparent to those skilled in the art, and generic principles defined herein may be applied to other embodiments. Thus, many changes and modifications may be made by one having ordinary skill in the art, without departing from the scope of the subject technology.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. All structural and functional equivalents to the elements of the various embodiments described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

What is claimed is:

1. A system for magnetic detection, comprising:
a magneto-optical defect center material comprising magneto-optical defect centers;
an optical excitation source mounted to a laser optical assembly that is selectively adjustable in a first axial direction in a first plane relative to the magneto-optical defect center material; and
a light collection assembly comprising a light pipe, an optical filter, and a lens, wherein the light collection assembly is configured to transmit light emitted from the magneto-optical defect center material to an optical detector, the light collection assembly being selectively adjustable in a second axial direction in the first plane relative to the magneto-optical defect center material.

2. The system of claim 1, wherein the laser optical assembly is selectively adjustable relative to a second plane relative to the magneto-optical defect center material, the second plane being perpendicular to the first plane.

3. The system of claim 2, wherein the laser optical assembly is selectively adjustable relative to a third plane relative to the magneto-optical defect center material, the third plane being orthogonal to the first plane and the second plane.

4. The system of claim 1, wherein the laser optical assembly comprises a plurality of flexure ribs.

5. The system of claim 1, wherein the laser optical assembly comprises a tilt flexure assembly.

6. The system of claim 1, wherein the laser optical assembly comprises a tip flexure assembly.

7. The system of claim 1, wherein the light collection assembly is selectively adjustable in the second axial direction with a removable light collection assembly adjustment tool.

8. The system of claim 1, wherein the light pipe is a hollow tube.

9. The system of claim 1, wherein the lens is integrated into the light pipe.

10. The system of claim 1, wherein the light pipe has a first end proximate the magneto-optical defect center material and a second end proximate the lens.

11. A magnetic detection system comprising:
means for securing a magneto-optical defect center material in a fixed position;
means for adjusting a laser mount assembly relative to the magneto-optical defect center material; and
means for adjusting a light collection assembly mount relative to the magneto-optical defect center material.

12. A laser optical assembly, comprising:
a tip and tilt flexure assembly selectively adjustable relative to a first plane and a second plane, the second plane being perpendicular to the first plane, the tip and tilt flexure assembly comprising:
a first frame member portion;
a second frame member portion coupled to the first frame member portion by a tilt flexure rib; and
a third frame member portion coupled to the second frame member portion by a tip flexure rib; and
a Z-axis adjustment assembly selectively adjustable relative to a third plane, the third plane being orthogonal to the first plane and the second plane, the Z-axis adjustment assembly comprising:
an outer frame member;
a laser mount; and
a plurality of flexure ribs coupling the outer frame member to the laser mount.

13. The laser optical assembly of claim 12, wherein a first tilt angle of the first frame member portion relative to the second frame member portion is selectively adjustable with a first nudger.

14. The laser optical assembly of claim 13, wherein a second tilt angle of the second frame member portion relative to the third frame member portion is selectively adjustable with a second nudger.

15. The laser optical assembly of claim 12, wherein the tip and tilt flexure assembly further comprises a fixation strap securing the first frame member portion relative to the second frame member portion.

16. The laser optical assembly of claim 12, wherein the tip and tilt flexure assembly further comprises a fixation strap securing the second frame member portion relative to the third frame member portion.

17. The laser optical assembly of claim 12, wherein the plurality of flexure ribs comprises four sets of five flexure ribs.

18. The laser optical assembly of claim 12, wherein the laser mount is selectively adjustable relative to the outer frame member with a Z-axis adjustment component.

19. The laser optical assembly of claim 18, wherein the Z-axis adjustment component comprises a threaded rod coupled to a plurality of nuts, the plurality of nuts secured relative to the laser mount and the outer frame member.

20. The laser optical assembly of claim 19, further comprising a set screw used to secure the threaded rod relative to the outer frame member.

21. The laser optical assembly of claim 18, wherein a maximum movement of the laser mount relative to the outer frame member is limited using a motion limiter.

22. The laser optical assembly of claim 21, wherein the motion limiter is a T-shaped member.
